(19) United States
(12) Patent Application Publication
(10) Pub. No.: US 2022/0181848 A1
(43) Pub. Date: Jun. 9, 2022

(54) LASER WITH HEXAGONAL SEMICONDUCTOR MICRODISK IN DOUBLE-TRIANGULAR WHISPERING-GALLERY OPTICAL RESONANCE MODE

(71) Applicant: SOOCHOW UNIVERSITY, Suzhou (CN)

(72) Inventors: Bing CAO, Suzhou (CN); Geng HE, Suzhou (CN); Qinhua WANG, Suzhou (CN); Xianjie XIONG, Suzhou (CN); Zhihao YUAN, Suzhou (CN); Hao ZHOU, Suzhou (CN); Anlin LUO, Suzhou (CN); Wangyibo CHEN, Suzhou (CN); Liyue XU, Suzhou (CN)

(21) Appl. No.: 17/440,775

(22) PCT Filed: Sep. 30, 2020
(86) PCT No.: PCT/CN2020/119163

§ 371 Date: Sep. 19, 2021

(30) Foreign Application Priority Data
Nov. 18, 2019 (CN) 201911124274.0

(51) Int. Cl. H01S 5/10; H01S 5/04

(52) U.S. Cl. CPC H01S 5/1075; H01S 5/1042; H01S 5/041

(57) ABSTRACT

A method for numerical control milling, forming and polishing of a large-diameter aspheric lens to solve long time-consuming and severe tool wear in the machining of a meter-scale large-diameter aspheric surface is disclosed. An aspheric surface is discretized into a series of rings with different radii, and the rings are sequentially machined through generating cutting by using an annular grinding wheel tool; the rings are equally spaced, there are a total of N rings, and the width of any ring is jointly determined by the N^{th} ring, the (N-1)th ring, positioning accuracy, and a generatrix equation of the aspheric lens, and the n^{th} ring has a curvature radius of Rn =sqrt(R0²-k*(n*dx)²); and the aspheric surface is enveloped by a large number of rings. The tool used for machining has a diameter greater than the semi-diameter of the aspheric surface, and contact area between tool and workpiece surface is rings.

### TECHNICAL FIELD

The present invention relates to the field of semiconductor microcavity lasers, and in particular, to a laser with a hexagonal semiconductor microdisk in a double-triangular whispering-gallery optical resonance mode.

### BACKGROUND

Semiconductor materials have high application values in the fields of micro-nano light-emitting devices and photoelectric integration and therefore have attracted wide attention from scientists. Especially, semiconductors with a high refractive index and a direct bandgap, such as GaN, ZnO, GaAs, InP, and perovskite, can be directly used as gain materials and resonators to prepare microcavity lasers. In addition, detectors and light-emitting devices made from compounds such as GaInN, AlGaN, and GalnAs can further cover wide bands of ultraviolet, visible light and near infrared. A whispering-gallery mode microcavity laser has been widely studied because it complies with the principle that light is totally reflected on a dielectric surface to form periodic resonance. Compared with Fabry-Pérot mode, this mode has the advantages of a small size, a high quality factor, a low threshold, ease of integration, etc. Whispering-gallery mode microcavity lasers based on semiconductor materials can be used in optical communication, optical storage, chemical and biological detection and other fields.

Currently reported semiconductor whispering-gallery mode microcavity lasers under research mainly use a microdisk structure, where a hexagonal microdisk is widely studied. This is because most semiconductors with a wide band gap and a direct bandgap have a wurtzite structure, and therefore the microdisk obtained by epitaxial growth has a hexagonal prism geometry. In addition, in the study of optical modes of a hexagonal resonator, reported modes are mostly hexagonal and triangular whispering-gallery modes, e.g., a hexagonal whispering-gallery mode solution (see [Rui Chen and Bo Ling, “Room Temperature Excitonic Whispering Gallery Mode Lasing from High-Quality Hexagonal ZnO Microdisks”, Advanced Materials, vol. 23, no. 19.pp. 2199+, 2011]) and a triangular whispering-gallery mode solution (see [Kouno T, “Lasing Action on Whispering Gallery Mode of Self-Organized GaN Hexagonal Microdisk Crystal Fabricated by RF-Plasma-Assisted Molecular Beam Epitaxy”, IEEE Journal of Quantum Electronics, vol. 47, no. 12, pp. 1565-1570,2011]). According to the theoretical research by Wiersig, J. (see [“Hexagonal dielectric resonators and microcrystal lasers”, Physical Review A, vol. 67, no. 2, pp. 12, 2003]), a hexagonal whispering-gallery mode optical path is located at the edge of a resonator, and the light can be emergent from a corner due to the optical diffraction principle, but its quality factor is much lower than that of the triangular whispering-gallery mode. In addition, a reflection area of light in the triangular whispering-gallery mode is located at the center of each side of a hexagon, which makes it difficult for internally circulating light to exit, hence reducing luminous efficiency of the laser. Therefore, the two problems degrade the performance of a laser with a hexagonal semiconductor microdisk.

### SUMMARY

In view of this, a main objective of the present invention is to provide a laser with a hexagonal semiconductor microdisk in a double-triangular whispering-gallery optical resonance mode, to overcome the shortcomings in existing solutions that a hexagonal whispering-gallery mode has a low quality factor and a triangular whispering-gallery mode has difficulty in light exiting. The laser with a hexagonal semiconductor microdisk in a double-triangular whispering-gallery optical resonance mode has the advantages of a high quality factor and ease of light exiting.

To achieve the above objective, the present invention provides a laser with a hexagonal semiconductor microdisk in a double-triangular whispering-gallery optical resonance mode, including a reflecting substrate, a hexagonal semiconductor microdisk, and a laser, where the hexagonal semiconductor microdisk is arranged on the reflecting substrate; emergent light of the laser is perpendicular to a surface of the hexagonal semiconductor microdisk and irradiates any one of six corners of the hexagonal semiconductor microdisk; and laser light in a double-triangular whispering-gallery optical resonance mode horizontally exits from one of six side walls of the hexagonal semiconductor microdisk.

In a preferred solution, the laser is a single-mode high power laser, a wavelength of emergent laser light is smaller than that of a band gap of a semiconductor material used, the hexagonal semiconductor microdisk has a regular hexagonal surface, a side surface of the hexagonal semiconductor microdisk is perpendicular to the surface and is smooth, and the surface of the reflecting substrate is a smooth plane. The optical resonance strong light loss is reduced, so that the stability of an emergent laser spectrum is enhanced.

Further, the intensity and line width of the emergent light of the laser with the microdisk can be changed by adjusting the emergent power of the laser.

Further, a size of an excitation area at the corner of the hexagonal semiconductor microdisk which the laser irradiates is smaller than that of the surface of the hexagonal semiconductor microdisk.

Further, a stability of the laser light in the double-triangular whispering-gallery mode is adjusted by adjusting a size of an irradiation spot of the laser.

With the above-mentioned technical solutions, the present invention has the following beneficial effects: Compared with existing solutions of a laser in a hexagonal whispering-gallery mode and a laser in a triangular whispering-gallery mode, the laser with a hexagonal semiconductor microdisk in a double-triangular whispering-gallery optical resonance mode according to the present invention has the advantages of a high quality factor and ease of light exiting.

### BRIEF DESCRIPTION OF DRAWINGS

FIG. 1 is a schematic diagram of a laser with a hexagonal semiconductor microdisk provided by the present invention;

FIG. 2 is a scanning electron microscope picture of a gallium nitride microdisk;

FIG. 3 shows an output spectrum of a gallium nitride laser;

FIG. 4 is a diagram of a simulated light field in a double-triangular whispering-gallery mode;

FIG. 5 is a function diagram of the number of reflections and a quality factor of a double-triangular whispering-gallery mode;

FIG. 6a is a diagram of a simulated light field in which the ratio of an excitation area to a resonator area is 5%;

FIG. 6b is a diagram of a simulated light field in which the ratio of an excitation area to a resonator area is 15%;

FIG. 6c is a diagram of a simulated light field in which the ratio of an excitation area to a resonator area is 20%; and

FIG. 6d is a diagram of a simulated light field in which the ratio of an excitation area to a resonator area is 30%.

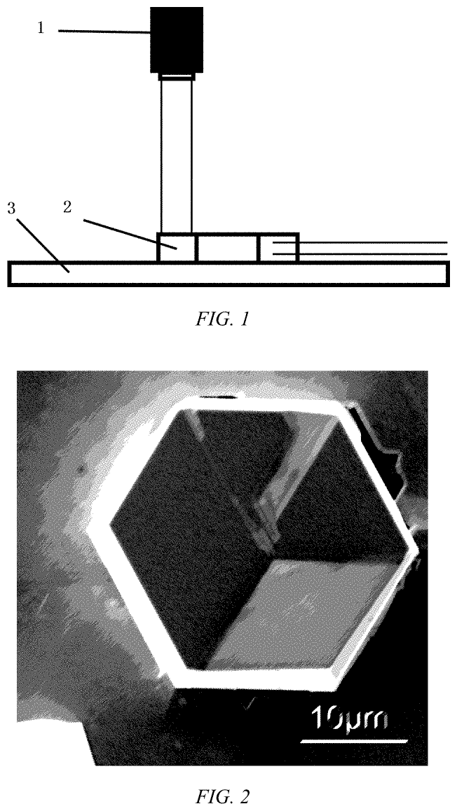

In FIG. 1: 1: reflecting substrate; 2: hexagonal semiconductor microdisk; 3: laser.

### DESCRIPTION OF EMBODIMENTS

To make the objectives, technical solutions, and advantages of the present invention clearer, the following further describes the present invention in detail with reference to specific embodiments and the accompanying drawings.

### Embodiment 1

As shown in the FIG. 1, a laser with a hexagonal semiconductor microdisk in a double-triangular whispering-gallery optical resonance mode includes: a reflecting substrate 1, a hexagonal semiconductor microdisk 2, and a laser 3, where the hexagonal semiconductor microdisk is arranged on the reflecting substrate; emergent light of the laser is perpendicular to a surface of the hexagonal semiconductor microdisk and irradiates any one of six corners of the hexagonal semiconductor microdisk; and laser light in a double-triangular whispering-gallery optical resonance mode horizontally exits from one of six side walls of the hexagonal semiconductor microdisk.

The laser with a hexagonal semiconductor microdisk in a double-triangular whispering-gallery optical resonance mode in the present invention relates to the following specific working principle.

In the present invention, optical excitation is mainly performed on part of the semiconductor microdisk so as to control the output of the laser mode. In laser excitation methods reported in the past, a laser spot completely covers the microdisk. Under this condition, only the hexagonal whispering-gallery mode and the triangular whispering-gallery mode can be excited. In contrast, the semiconductor microdisk of the present invention has a larger diameter, and therefore the light spot of the conventional laser pump source can cover only part of the microdisk. Because of the spatiality of stimulated radiation characteristics, i.e., population inversion occurs only in an excited working material area and only an optical path in this area is enhanced, when the excitation light spot is located only in a corner of the hexagonal microdisk, resonance occurs only in an optical mode with an optical path under a light spot. The optical path in this double-triangular whispering-gallery mode is located at a corner of the hexagonal microdisk, so that the optical mode can be effectively amplified by stimulated radiation.

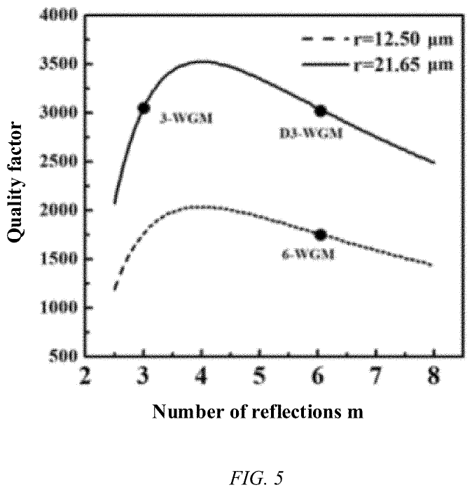

Based on the formula

$$Q = \frac{π {mnrR}^{m \text{/} 4}}{λ ( 1 - {R}^{m \text{/} 2} )} sin ( \frac{2 π}{m} ) ,$$

where m is the number of reflections, r is the radius of a circumcircle of the hexagon, and R is effective reflectivity, it can be concluded that under the same effective reflectivity, the quality factor of the double-triangular whispering-gallery mode is similar to that of the triangular whispering-gallery mode, but significantly higher than that of the hexagonal whispering-gallery mode. FIG. 4 shows a diagram of a simulated light field in a double-triangular whispering-gallery mode. An excitation area is in a white frame, and a regular hexagon is a semiconductor resonator, with its periphery being air. An outermost frame is a perfect matching layer serving as an absorption layer, and a bright color area in the hexagon is an area with a high light intensity density, i.e., an optical path. In addition, the optical path of the double-triangular whispering-gallery mode is located at a corner of the hexagonal microdisk, and the resonant light in the double-triangular whispering-gallery mode is easier to exit due to an optical diffraction effect of the corner.

### Embodiment 2

A laser with a hexagonal semiconductor microdisk in a double-triangular whispering-gallery optical resonance mode is provided, where the reflecting substrate, the hexagonal semiconductor microdisk and the laser are sequentially configured as a monocrystalline silicon reflecting substrate, a gallium nitride hexagonal microdisk and an ultraviolet pulse laser. The ultraviolet pulse laser has a wavelength of 325 nm, a line width of 100 fs, and a frequency of 1kHz; a light spot thereof has a diameter of 10 μm; the gallium nitride hexagonal microdisk has a diameter of 25 μm; and an excitation area irradiated on any one of six corners of the gallium nitride hexagonal microdisk is square. The excitation area is a specialized term in this field. In this embodiment, the ultraviolet pulse laser irradiates the gallium nitride hexagonal microdisk, and the excitation area is an area in which the ultraviolet pulse laser light excites gallium nitride.

The Comsol Multiphysics simulation software is used to identify conditions the most suitable for light exiting in the double-triangular whispering-gallery mode. A hexagonal resonator model is constructed with its periphery being air, and an edge area is arranged as a perfect matching layer. Electric field excitation is set in the corners of the hexagonal resonator, and an excitation area is square.

By changing the square area of the excitation area, the ratio of the excitation area to the hexagonal area is adjusted. Changes in light field distribution can be observed from light field simulation results, i.e., the optical mode in the hexagonal resonator has changed.

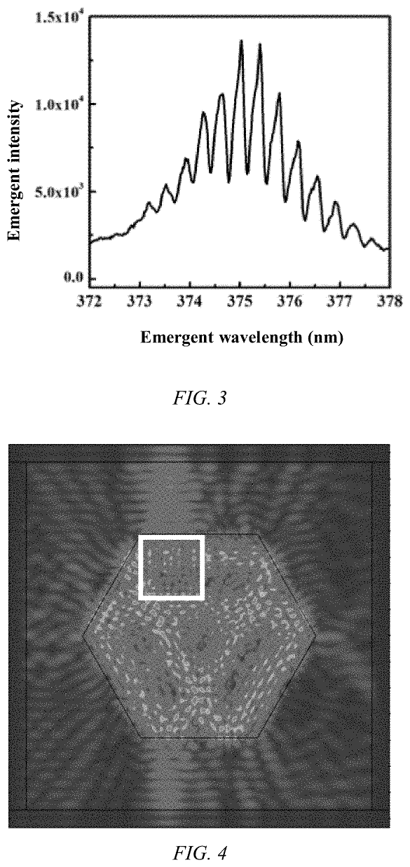

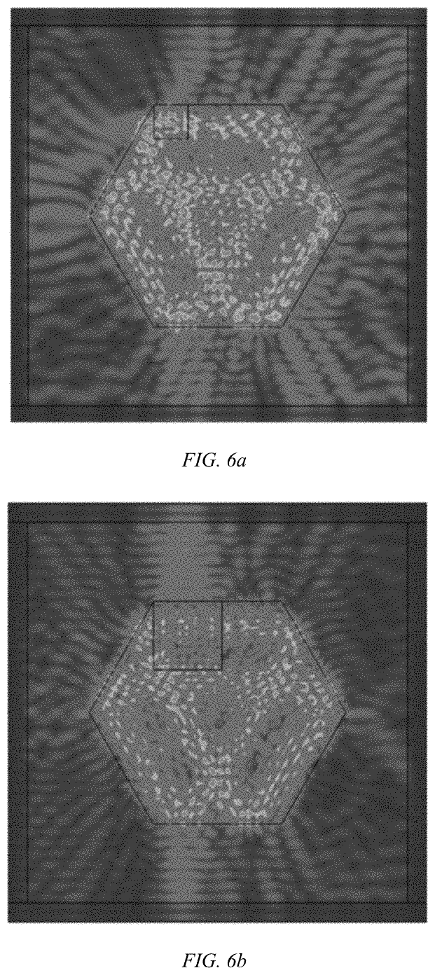

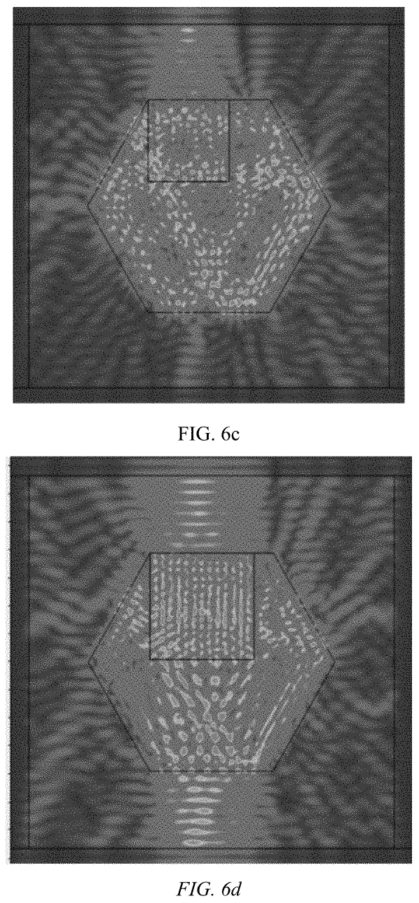

To verify the effect of the technical solution of the present invention, experimental verification is performed. In the experiment, the ultraviolet pulse laser has a wavelength of 325 nm, a line width of 100 fs, and a frequency of 1kHz, and a light spot thereof has a diameter of 10 82 m. FIG. 2 is a scanning electron microscope picture of a gallium nitride microdisk. It can be learned that in the experiment, the gallium nitride hexagonal microdisk has a diameter of 25 μm. FIG. 3 shows an output spectrum of a gallium nitride laser. Based on the formula Δλ=λ²/[L(n−λdn/dλ)], where λ is an emergent wavelength of the laser with the microdisk. It can be learned from FIG. 3 that, λ is about 375 nm, and L is the total length of one cycle of an optical path. It can be learned that, the double-triangular whispering-gallery mode has an interval of 0.35 nm, which is quite close to an experimental result of 0.36 nm, proving that the obtained result is the laser light exiting in the double-triangular whispering-gallery mode. In addition, the quality factor is calculated by using the formula Q=λ/Δλ, and an obtained Q value is as high as 3049. FIG. 4 is a diagram of a simulated light field in a double-triangular whispering-gallery mode, which also proves that the laser mode is the double-triangular whispering-gallery mode. FIG. 5 is a function diagram of the number of reflections and a quality factor of a double-triangular whispering-gallery mode. This diagram marks values corresponding to quality factors of the three whispering-gallery modes in the same resonator. It can be learned that, the quality factor corresponding to the double-triangular whispering-gallery mode (D3-WGM) is higher than that of the hexagonal whispering-gallery mode (6-WGM). FIG. 6a to FIG. 6d are diagrams of stimulated light fields sequentially corresponding to cases that the ratio of the excitation area to the resonator area is 5%, 15%, 20% and 30%, respectively. It is found from the simulation results that, with regard to the ratio of the excitation area to the hexagonal resonator area, 20% is most suitable for stable and efficient output of laser light in the double-triangular whispering-gallery mode. This is because the double-triangular whispering-gallery mode is gradually destroyed when the area ratio is further increased, as shown in FIG. 6d, and thus an optimal solution can be obtained when the maximum excitation area ratio and the stability of the double-triangular whispering-gallery mode are ensured.

It is also found from the experiment that, the material of the hexagonal semiconductor microdisk is one or more selected from a group consisting of GaN, AN, GaAs, InAs, ZnO, InP, CdS and perovskite. The laser output in the double-triangular whispering-gallery optical resonance mode can be realized by using this solution, and the quality factor is greatly improved. All the listed materials feature a high refractive index. By using the physical characteristics of stimulated radiation of gain materials with a high refractive index, the reflecting substrate provides light reflection on the bottom surface to reduce an optical loss of a microcavity laser in the vertical direction, and the hexagonal semiconductor microdisk serves as an optical resonator and laser gain material. As an optical pump source, the laser provides an optical gain, and when the power of the pump source exceeds a microcavity laser threshold, generates laser light for exiting. By controlling a laser spot of the pump source to be located at a corner of the hexagonal microdisk, the laser light in the double-triangular whispering-gallery optical resonance mode is generated after stimulated radiation for exiting. Compared with conventional lasers in hexagonal and triangular whispering-gallery optical resonance modes, the present invention has the advantages of a high quality factor and ease of laser exiting.

The above-mentioned specific embodiments further explain the objectives, technical solutions and beneficial effects of the present invention in detail. It should be understood that the above-mentioned descriptions are merely specific embodiments of the present invention, and are not intended to limit the present invention. Any modification, equivalent replacement, improvement, etc. made within the spirit and principles of the present invention should fall within the protection scope of the present invention.

What is claimed is:

1. A laser with a hexagonal semiconductor microdisk in a double-triangular whispering-gallery optical resonance mode, comprising a reflecting substrate, a hexagonal semiconductor microdisk, and a laser, wherein the hexagonal semiconductor microdisk is arranged on the reflecting substrate; emergent light of the laser is perpendicular to a surface of the hexagonal semiconductor microdisk and irradiates any one of six corners of the hexagonal semiconductor microdisk; and laser light in the double-triangular whispering-gallery optical resonance mode horizontally exits from one of six side walls of the hexagonal semiconductor microdisk.

2. The laser with a hexagonal semiconductor microdisk in a double-triangular whispering-gallery optical resonance mode according to claim 1, wherein the laser is a high power laser, a wavelength of emergent laser light is smaller than that of a band gap of a hexagonal semiconductor microdisk material used, and the hexagonal semiconductor microdisk has a regular hexagonal surface.

3. The laser with a hexagonal semiconductor microdisk in a double-triangular whispering-gallery optical resonance mode according to claim 2, wherein an intensity and a line width of the emergent light of the laser with the hexagonal microdisk are controlled by an emergent power of the laser.

4. The laser with a hexagonal semiconductor microdisk in a double-triangular whispering-gallery optical resonance mode according to claim 1, wherein a size of an excitation area at the corner of the hexagonal semiconductor microdisk which the laser irradiates is smaller than that of the surface of the hexagonal semiconductor microdisk.

5. The laser with a hexagonal semiconductor microdisk in a double-triangular whispering-gallery optical resonance mode according to claim 1, wherein a stability of the laser in the double-triangular whispering-gallery mode is controlled by a size of an irradiation spot of the laser.

6. The laser with a hexagonal semiconductor microdisk in a double-triangular whispering-gallery optical resonance mode according to claim 1, wherein the reflecting substrate, the hexagonal semiconductor microdisk and the laser are sequentially configured as a monocrystalline silicon reflecting substrate, a gallium nitride hexagonal microdisk and an ultraviolet pulse laser; the ultraviolet pulse laser has a wavelength of 325 nm, a line width of 100 fs, and a frequency of 1 kHz, and a light spot thereof has a diameter of 10 μm; and the gallium nitride hexagonal microdisk has a diameter of 25 82 m.

7. The laser with a hexagonal semiconductor microdisk in a double-triangular whispering-gallery optical resonance mode according to claim 1, wherein the material of the hexagonal semiconductor microdisk is one or more selected from a group consisting of GaN, AlN, GaAs, InAs, ZnO, InP, and CdS.
